(19) United States
(12) Patent Application Publication
(10) Pub. No.: US 2026/0197952 A1
(43) Pub. Date: Jul. 9, 2026

(54) DISPLAY DEVICE AND ELECTRONIC DEVICE INCLUDING THE DISPLAY DEVICE

(71) Applicant: Samsung Display Co., LTD., Yongin-si (KR)

(72) Inventors: SEOKCHAN LEE, Yongin-si (KR); DONGJIN PARK, Yongin-si (KR); DONGWOO SEO, Yongin-si (KR); Mina Woo, Yongin-si (KR); Dongjin Yoon, Yongin-si (KR)

(21) Appl. No.: 19/272,573

(22) Filed: Jul. 17, 2025

(30) Foreign Application Priority Data
Jan. 7, 2025 (KR) 10-2024-0002453

(51) Int. Cl. H05K 5/02; H01L 23/31

(52) U.S. Cl. CPC H05K 5/0217; H10W 74/114

(57) ABSTRACT

A display device includes a display module, a window arranged on the display module and including a bottom surface facing the display module and a top surface opposite the bottom surface and facing away from the display module, a lower film arranged under the display module, and a plate arranged under the lower film. The plate includes a first non-folding portion, a second non-folding portion, a third non-folding portion, a first folding portion between the first non-folding portion and the second non-folding portion, and a second folding portion between the second non-folding portion and the third non-folding portion. A first curvature of the first folding portion and a second curvature of the second folding portion are different from each other in a folded state of the display device, and a center of the second curvature is located between the first non-folding portion and a midplane of the display device.

This application claims priority to Korean Patent Application No. 10-2024-0002453 filed on Jan. 7, 2025, and all the benefits accruing therefrom under 35 U.S.C. § 119, the content of which in its entirety is herein incorporated by reference.

### BACKGROUND

### 1. Field

The disclosure relates to a display device and an electronic device including the display device.

### 2. Description of the Related Art

Various types of electronic devices are being used to provide image information, and recently, electronic devices including flexible display modules that are foldable or bendable have been developed. Flexible electronic devices, unlike rigid electronic devices, may be variously changed in shape, such as by being folded, rolled, or bent, and thus may be carried regardless of the size of a displayed screen.

Technologies are being developed to make flexible electronic devices thinner, and in particular, technologies are being developed to make flexible electronic devices thinner when the flexible electronic devices are folded or bent.

The above-described information disclosed in the technology section that serves as the background of the disclosure is for improving the understanding of the background of the disclosure, and thus may include information that does not constitute related art.

### SUMMARY

The disclosure provides a thinner display device and an electronic device including the same.

However, technical problems to be solved by the disclosure are not limited to the problem, and other problems not mentioned may be clearly understood by those of ordinary skill in the art from the description of the disclosure described herein.

According to an aspect of the disclosure, a display device includes a display module, a window arranged on the display module and including a bottom surface facing the display module and a top surface opposite the bottom surface and facing away from the display module, a lower film arranged under the display module, and a plate arranged under the lower film and including a first non-folding portion, a second non-folding portion, a third non-folding portion, a first folding portion between the first non-folding portion and the second non-folding portion, and a second folding portion between the second non-folding portion and the third non-folding portion, in which a first curvature of the first folding portion and a second curvature of the second folding portion are different from each other in a folded state of the display device, and a center of the second curvature is located between the first non-folding portion and a midplane between the second non-folding portion and the third non-folding portion.

In an embodiment, the second curvature may be greater than the first curvature.

In an embodiment, in folding, a first volume from the midplane to the second folding portion in a direction toward the first non-folding portion may be greater than a second volume from the midplane to the second folding portion in a direction opposite the direction toward the first non-folding portion.

In an embodiment, the second folding portion may include a reverse curvature portion folded according to a third curvature, a constant curvature portion folded according to the second curvature, and a non-curvature portion, which are sequentially arranged.

In an embodiment, the constant curvature portion may include a plurality of first holes, and the reverse curvature portion may include a plurality of second holes.

In an embodiment, a size of each first hole of the plurality of first holes may be greater than a size of each second hole of the plurality of second holes.

In an embodiment, the third curvature may be less than the second curvature.

In an embodiment, the window may include a thin film glass substrate, the thin film glass substrate may include a thin film portion overlapping the first folding portion and the second folding portion and a thick film portion overlapping the first non-folding portion, the second non-folding portion and the third non-folding portion, and a thickness of the thick film portion may be greater than a thickness of the thin film portion.

In an embodiment, the thin film portion may include a first thin film portion overlapping the first folding portion and a second thin film portion overlapping the second folding portion, and a thickness of an area of the second thin film portion overlapping the reverse curvature portion may be greater than a thickness of an area of the second thin film portion overlapping the constant curvature portion.

In an embodiment, in the second thin film portion, the thickness of the area of the second thin film portion overlapping the reverse curvature portion may be less than a thickness of an area of the second thin film portion overlapping the non-curvature portion.

According to another aspect of the disclosure, a display device includes a display module, a window arranged on the display module and including a bottom surface facing the display module and a top surface opposite the bottom surface and facing away from the display module, a lower film arranged under the display module, and a plate arranged under the lower film and including a first non-folding portion, a second non-folding portion, a third non-folding portion, a first folding portion between the first non-folding portion and the second non-folding portion, and a second folding portion between the second non-folding portion and the third non-folding portion, in which, in a folded state of the display device, the first folding portion is folded according to a first curvature, and the second folding portion is folded according to a second curvature, and, with respect to a midplane between the second non-folding portion and the third non-folding portion, a first volume from the midplane to the second folding portion in a direction toward the first non-folding portion is greater than a second volume from the midplane to the second folding portion in a direction opposite the direction toward the first non-folding portion.

In an embodiment, the second curvature may be greater than the first curvature.

In an embodiment, a first curvature of the first folding portion and a second curvature of the second folding portion may be different from each other in folding, and a center of the second curvature may be located between the midplane and the first non-folding portion.

In an embodiment, the second folding portion may include a reverse curvature portion folded according to a third curvature, a constant curvature portion folded according to the second curvature, and a non-curvature portion, which are sequentially arranged.

In an embodiment, the constant curvature portion may include a plurality of first holes, and the reverse curvature portion may include a plurality of second holes.

In an embodiment, a size of each first hole of the plurality of first holes may be greater than a size of each second hole of the plurality of second holes.

In an embodiment, the third curvature may be less than the second curvature.

In an embodiment, the window may include a thin film glass substrate, the thin film glass substrate may include a thin film portion overlapping the first folding portion and the second folding portion and a thick film portion overlapping the first non-folding portion, the second non-folding portion and the third non-folding portion, and a thickness of the thick film portion may be greater than a thickness of the thin film portion.

In an embodiment, the thin film portion may include a first thin film portion overlapping the first folding portion and a second thin film portion overlapping the second folding portion, and a thickness of an area of the second thin film portion overlapping the reverse curvature portion may be greater than a thickness of an area of the second thin film portion overlapping the constant curvature portion.

According to another aspect of the disclosure, an electronic device includes a display device, in which the display device includes a display module, a window arranged on the display module and including a bottom surface facing the display module and a top surface opposite the bottom surface and facing away from the display module, a lower film arranged under the display module, and a plate arranged under the lower film and including a first non-folding portion, a second non-folding portion, a third non-folding portion, a first folding portion between the first non-folding portion and the second non-folding portion, and a second folding portion between the second non-folding portion and the third non-folding portion, in which a first curvature of the first folding portion and a second curvature of the second folding portion are different from each other in a folded state of the display device, and a center of the second curvature is located between the first non-folding portion and a midplane between the second non-folding portion and the third non-folding portion.

### BRIEF DESCRIPTION OF THE DRAWINGS

The following drawings attached to this specification illustrate example embodiments of the disclosure, and serve to further understand the technical idea of the disclosure together with the detailed description of the disclosure described later, such that the disclosure should not be construed as being limited to the matters illustrated in such drawings in which:

FIG. 1 is an assembled perspective view of an electronic device according to an embodiment of the disclosure;

FIG. 2A is a perspective view of a folded electronic device according to an embodiment of the disclosure;

FIG. 2B is a cross-sectional view of a folded display device according to an embodiment of the disclosure;

FIG. 3A is a perspective view of a folded electronic device according to another embodiment of the disclosure;

FIG. 3B is a cross-sectional view of a folded display device according to another embodiment of the disclosure;

FIG. 4A is an exploded perspective view of an electronic device according to an embodiment of the disclosure;

FIG. 4B is a cross-sectional view illustrating that the display device of FIG. 2B is unfolded;

FIG. 4C is a cross-sectional view illustrating that the display device of FIG. 3B is unfolded;

FIG. 5 is a plan view illustrating a part of a folding unit according to an embodiment of the disclosure;

FIG. 6 is a block diagram of an electronic device according to an embodiment of the disclosure; and

FIG. 7 illustrates schematic diagrams of an electronic device according to various embodiments.

### DETAILED DESCRIPTION

The disclosure may have various modifications thereto and various embodiments, and thus particular embodiments will be illustrated in the drawings and described in detail in a detailed description. Effects and features of the disclosure, and methods for achieving them will become clear with reference to the embodiments described later in detail together with the drawings. However, the disclosure is not limited to the embodiments disclosed below and may be implemented in various forms.

In the following embodiments, the terms such as first, second, and the like, have been used to distinguish one component from other components, rather than limiting.

In the following embodiments, singular forms include plural forms unless apparently indicated otherwise contextually.

In the following embodiments, the terms “include”, “have”, or the like, are intended to mean that there are features, or components, described herein, but do not preclude the possibility of adding one or more other features or components.

In the following embodiments, when a portion, such as a film, a region, a component, or the like, is present on or above another portion, this case may include not only a case where it is directly on the other portion, but also a case where another film, region, component, or the like is arranged between the portion and the other portion.

In the following embodiments, terms such as connect or combine do not necessarily imply a direct and/or fixed connection or combination of two members, unless the context clearly indicates otherwise, and do not exclude the presence of another member between the two members.

In the drawings, the size of components may be exaggerated or reduced for convenience of description. For example, as the size and thickness of each component illustrated in the drawings are arbitrarily illustrated for convenience of description, the disclosure is not necessarily limited to the illustration.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

Hereinafter, embodiments of the disclosure will be described in detail with reference to the attached drawings, and in the description with reference to the drawings, identical or corresponding components are given the same reference numerals and redundant descriptions thereof will be omitted.

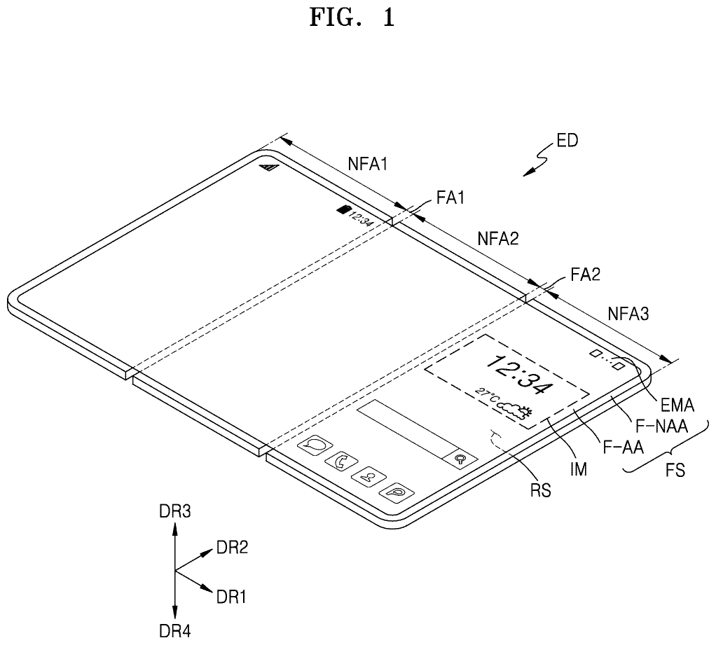

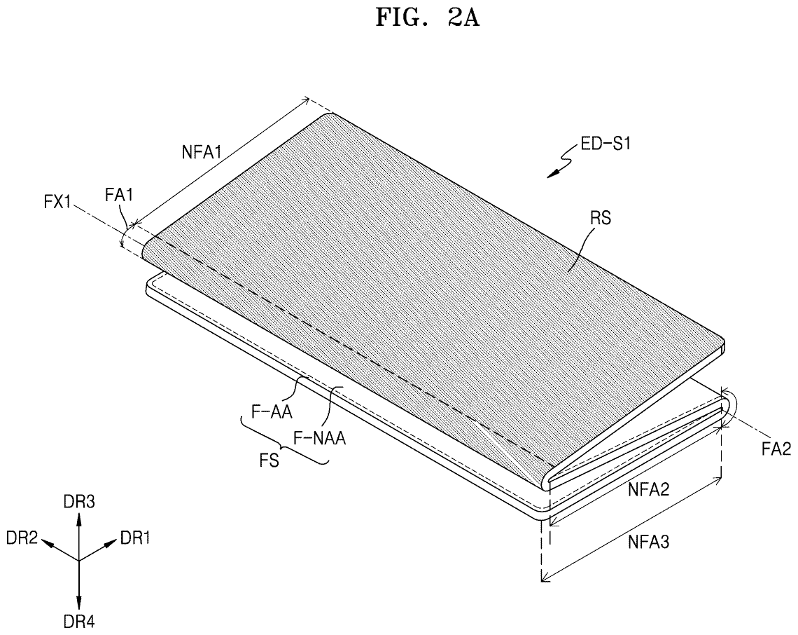

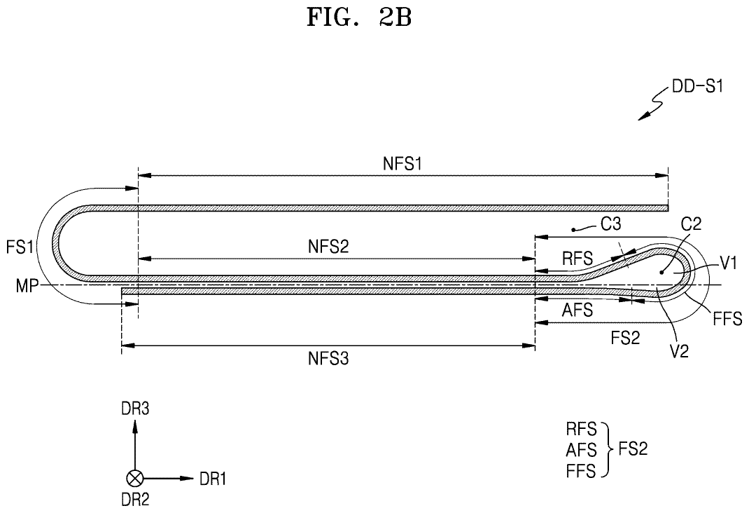

FIG. 1 is an assembled perspective view of an electronic device according to an embodiment of the disclosure. FIG. 2A is a perspective view of a folded electronic device according to an embodiment of the disclosure. FIG. 2B is a cross-sectional view of a folded display device according to an embodiment of the disclosure.

An electronic device ED according to the disclosure may be a device activated according to an electrical signal. For example, the electronic device ED may be a mobile phone, a tablet, a vehicle navigation system, a game console, or a wearable device, but embodiments of the present disclosure are not limited thereto. Herein, a mobile phone is illustrated as an example of the electronic device ED.

A first direction DR1 to a fourth direction DR4 are illustrated in FIG. 1 and the drawings below, and directions indicated by the first to fourth directions DR1, DR2, DR3, and DR4 described herein may be relative concepts and may be converted into other directions. Hereinafter, the directions indicated by the first to fourth directions DR1, DR2, DR3, and DR4 will be described as the first to fourth directions DR1, DR2, DR3, and DR4.

Referring to FIG. 1, the electronic device ED according to an embodiment may include a display surface FS that is parallel to a surface defined by the first direction DR1 and the second direction DR2 crossing the first direction DR1 in an unfolded state of the electronic device ED. The electronic device ED may provide an image IM to a user through the display surface FS. The electronic device ED according to an embodiment may display the image IM in a third direction DR3 on the display surface FS parallel to each of the first direction DR1 and the second direction DR2.

Herein, a front (or top) surface and a rear (or bottom) surface of each component may be defined with respect to a direction in which the image IM is displayed. Herein, the direction in which the image IM is displayed may be defined as the third direction DR3, and the fourth direction DR4 may be defined as a direction opposing the third direction DR3.

The electronic device ED according to an embodiment may detect an external input applied from outside. The external input may include various forms of inputs provided from outside the electronic device ED. For example, the external inputs may include contact by a part of a user's body, such as a hand of the user as well as an external input applied in proximity to or at a selected distance from the electronic device ED (e.g., hovering). The external inputs may have various forms such as force, pressure, temperature, light, or the like.

The display surface FS of the electronic device ED may include an active area F-AA and a peripheral area F-NAA. The active area F-AA may be a region that may be activated according to an electrical signal. The electronic device ED according to an embodiment may display the image IM through the active area F-AA. Various forms of external inputs may be detected in the active area F-AA. The peripheral area F-NAA may be adjacent to the active area F-AA. The peripheral area F-NAA may have a selected color.

The active area F-AA may include an electronic module area EMA. Various electronic modules may be arranged in the electronic module area EMA. For example, the electronic module may include at least one of a camera, a speaker, a light detection sensor, and a heat detection sensor. The electronic module area EMA may detect an external subject received through the display surface FS or provide a sound signal such as, for example, voice to the outside through the display surface FS. An electronic module may include a plurality of components and may not be limited to any one embodiment.

The electronic module area EMA may be surrounded by the active area F-AA and/or the peripheral area F-NAA. However, the disclosure is not limited thereto, and the electronic module area EMA may be arranged within the active area F-AA, and is not limited to any one embodiment. In an example in which electronic modules arranged in the electronic module area EMA are deactivated, the electronic module area EMA is not visible to the user and may display a video or an image on the display surface FS.

A rear surface RS of the electronic device ED according to an embodiment may be a surface opposing the display surface FS. In an embodiment, the rear surface RS may not display any videos or images on an outer surface of the electronic device ED. However, the disclosure is not limited thereto, and the rear surface RS may function as a display surface on which a video or an image is displayed. The electronic device ED according to an embodiment may further include an electronic module area arranged on the rear surface RS. A camera, a speaker, a light detection sensor, or other component may also be arranged in the electronic module area arranged on the rear surface RS.

In the electronic device ED according to an embodiment, the peripheral area F-NAA may surround the active area F-AA. Thus, the shape of the active area F-AA may be substantially defined by the peripheral area F-NAA. However, this is an example, and the peripheral area F-NAA may be arranged adjacent to one side of the active area F-AA or may be omitted. The electronic device ED according to an embodiment of the disclosure may include the active area F-AA of various shapes and is not limited to any one embodiment.

The electronic device ED according to an embodiment may include folding areas FA1 and FA2 and non-folding areas NFA1, NFA2, and NFA3. The electronic device ED may include a first non-folding area NFA1, a first folding area FA1, a second non-folding area NFA2, a second folding area FA2, and a third non-folding area NFA3 that are spaced apart from one another in the first direction DR1. The first non-folding area NFA1 and the second non-folding area NFA2 may be spaced apart from each other, with the first folding area FA1 between the first non-folding area NFA1 and the second non-folding area NFA2. The second non-folding area NFA2 and the third non-folding area NFA3 may be spaced apart from each other, with the second folding area FA2 between the second non-folding area NFA2 and the third non-folding area NFA3.

In the disclosure, the folding areas FA1 and FA2 may be areas corresponding to foldable portions among components included in the electronic device ED, and the non-folding areas NFA1, NFA2, and NFA3 may be areas corresponding to flat portions among the components included in the electronic device ED. Although FIG. 1 illustrates two folding areas FA1 and FA2 arranged between three non-folding areas NFA1, NFA2, and NFA3, the disclosure is not limited thereto, and any one of the folding areas FA1 and FA2 may be omitted, or the number of folding areas may be three or more, and the disclosure is not limited to any one embodiment.

Referring to FIG. 2A, in a folding mode according to an embodiment, an electronic device ED-S1 may include the first folding area FA1 that is folded with respect to a first folding axis FX1 extending in the second direction DR2 and the second folding area FA2 that is folded with respect to a second folding axis FX2 extending in the second direction DR2 and spaced apart from the first folding axis FX1 in the first direction DR1. However, the embodiment is not limited thereto, and the first folding axis FX1 and the second folding axis FX2 may be parallel in any direction other than the second direction DR2.

In the current embodiment, the first folding axis FX1 may be defined on the active area F-AA overlapping the first folding area FA1. Thus, as the first folding area FA1 is folded, the active area F-AA overlapping the first non-folding area NFA1 and the active area F-AA overlapping the second non-folding area NFA2 may be folded to face each other.

In the current embodiment, the second folding axis FX2 may be defined on the rear surface RS overlapping the second folding area FA2. Thus, as the second folding area FA2 is folded, the rear surface RS overlapping the second non-folding area NFA2 and the rear surface RS overlapping the third non-folding area NFA3 may be folded to face each other.

According to the current embodiment, in an example case in which a part of the electronic device ED-S1 is folded about the first folding axis FX1, the electronic device ED-S1 may be defined as being folded in an ‘inner-folding’ state, and in an example case in which a part of the electronic device ED-S1 is folded about the second folding axis FX2, the electronic device ED-S1 may be defined as being folded in an ‘outer-folding’ state. In the folded state, a curvature of the first folding area FA1 and a curvature of the second folding area FA2 may be the same as or different from each other, and are not limited to any one embodiment.

Recently, technology is being developed to reduce the thickness and weight of the electronic device ED-S1 for portability, storage, or the like. However, when a configuration in the first folding area FA1 and a configuration in the second folding area FA2 each form a symmetrical structure, there is a limit in reducing the thickness of the folded electronic device ED-S1. To solve this problem, the thickness of the folded electronic device ED-S1 may be reduced by making a folding area asymmetrical, specifically, by making a folding portion inclined toward the middle with respect to the thickness of the electronic device ED-S1.

Referring to FIG. 2B, a display device DD-S1 may include a first non-folding portion NFS1, a second non-folding portion NFS2, a third non-folding portion NFS3, a first folding portion FS1 between the first non-folding portion NFS1 and the second non-folding portion NFS2, and a second folding portion FS2 between the second non-folding portion NFS2 and the third non-folding portion NFS3. The electronic device ED-S1 described in FIG. 2A may include the display device DD-S1.

The display device DD-S1 may include the first non-folding portion NFS1, the first folding portion FS1, the second non-folding portion NFS2, the second folding portion FS2, and the third non-folding portion NFS3 that are sequentially arranged in the first direction DR1 in non-folding.

The first non-folding portion NFS1 may be arranged to overlap and correspond to the first non-folding area NFA1, the second non-folding portion NFS2 may be arranged to overlap and correspond to the second non-folding area NFA2, the third non-folding portion NFS3 may be arranged to overlap and correspond to the third non-folding area NFA3, the first folding portion FS1 may be arranged to overlap and correspond to the first folding area FA1, and the second folding portion FS2 may be arranged to overlap and correspond to the second folding area FA2.

In folding of the display device DD-S1, the first folding portion FS1 may have a first curvature and the second folding portion FS2 may have a second curvature. The first curvature and the second curvature may be different from each other. For example, the second curvature may be greater than the first curvature. The term “in folding of the display device DD-S1” recited herein may refer to a fully folded state or a partially folded state (i.e., during a folding operation) of the display device DD-S1, or further, a step of folding the display device DD-S1.

In the folded display device DD-S1, the second folding portion FS2 may be folded asymmetrically. That is, a center C2 of the second curvature of the second folding portion FS2 may be inclined closer to the first non-folding portion NFS1, and as a result, the thickness of the folded display device DD-S1 may be reduced with respect to the third direction DR3.

The center C2 of the second curvature may be located between the first non-folding portion NFS1 and a midplane MP between the second non-folding portion NFS2 and the third non-folding portion NFS3. The midplane MP may be defined as a plane between midpoints of a plane of the second non-folding portion NFS2 and a plane of the third non-folding portion NFS3, which are parallel to each other.

In folding of the display device DD-S1, a first volume V1 from the midplane MP to the second folding portion FS2 in a direction toward the first non-folding portion NFS1 may be greater than a second volume V2 from the midplane MP to the second folding portion FS2 in a direction opposite the direction toward the first non-folding portion NFS1. Specifically, when the folded display device DD-S1 is viewed from a plane defined by the first direction DR1 and the third direction DR3, an area from the midplane MP to the second folding portion FS2 above the midplane MP may be greater than an area from the midplane MP to the second folding portion FS2 under the midplane MP. A direction along the third direction DR3 will be referred to as an upper side, and a direction opposing the direction will be referred to as a lower side.

With respect to the non-folded display device DD-S1, the second folding portion FS2 may include a reverse curvature portion RFS that is folded according to a third curvature, a constant curvature portion FFS that is folded according to a second curvature, and a non-curvature portion AFS, which are sequentially arranged in the first direction DR1.

The reverse curvature portion RFS may be a region formed to have the third curvature in the second folding portion FS2 as the second folding portion FS2 is inclined toward the first non-folding portion NFS1. The third curvature of the reverse curvature portion RFS may be less than the second curvature of the constant curvature portion FFS.

In the folded display device DD-S1, a center C3 of the third curvature may be located on the top surface of the second non-folding portion NFS2 with respect to the third direction DR3. A line connecting the center C2 of the second curvature to the center C3 of the third curvature may pass through the display device DD-S1.

With the foregoing configuration, the display device DD-S1 may have a less thickness when folded, and thus the portability and compressibility of the display device DD-S1 and the electronic device ED-S1 including the display device DD-S1 may be improved.

Hereinbelow, as another example to reduce a thickness of an electronic device ED-S2 in folding, a display device DD-S2 is described in which a folding area is asymmetrical, specifically, a folding portion is inclined toward the middle with respect to the thickness of the electronic device ED-S2.

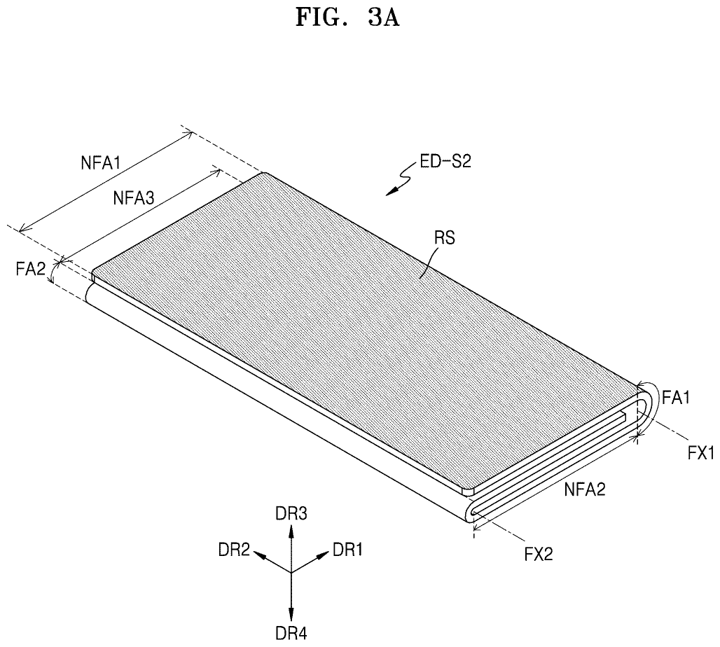

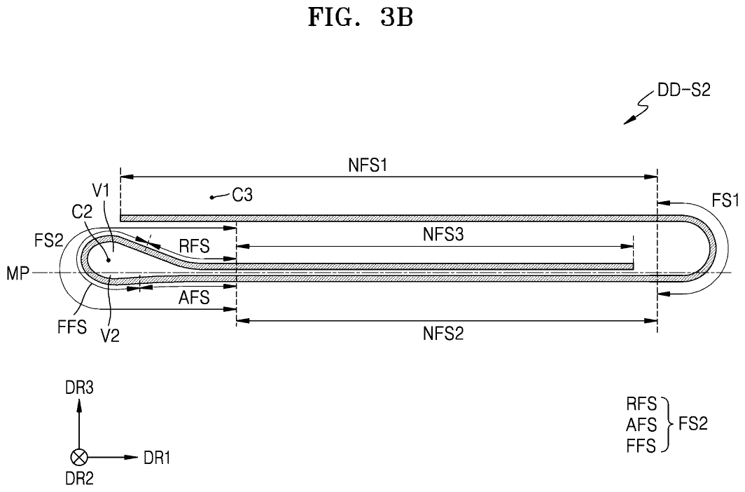

Referring to FIG. 3A, in the folding mode according to another embodiment, the electronic device ED-S2 may include the first folding area FA1 that is folded with respect to the first folding axis FX1 extending in the second direction DR2 and the second folding area FA2 that is folded with respect to the second folding axis FX2 extending in the second direction DR2 and spaced apart from the first folding axis FX1 in the first direction DR1. However, the embodiment is not limited thereto, and the first folding axis FX1 and the second folding axis FX2 may be parallel in any direction other than the second direction DR2.

In the current embodiment, the first folding axis FX1 may be defined on the active area F-AA overlapping the first folding area FA1. Thus, as the first folding area FA1 is folded, the rear surface RS overlapping the third non-folding area NFA3 and the active area F-AA overlapping the first non-folding area NFA1 may be folded to face each other.

In the current embodiment, the second folding axis FX2 may be defined on the active area F-AA overlapping the second folding area FA2. Thus, as the second folding area FA2 is folded, the active area F-AA overlapping the second non-folding area NFA2 and the active area F-AA overlapping the third non-folding area NFA3 may be folded to face each other.

According to the current embodiment, in an example case in which a part of the electronic device ED-S2 is folded about the first folding axis FX1 and/or the second folding axis FX2, the electronic device ED-S2 may be defined as being in the ‘inner-folding’ state. In the folded state, the curvature of the first folding area FA1 and the curvature of the second folding area FA2 may be the same as or different from each other, and are not limited to any one embodiment.

Referring to FIG. 3B, the display device DD-S2 may include the first non-folding portion NFS1, the second non-folding portion NFS2, the third non-folding portion NFS3, the first folding portion FS1 between the first non-folding portion NFS1 and the second non-folding portion NFS2, and the second folding portion FS2 between the second non-folding portion NFS2 and the third non-folding portion NFS3. The electronic device ED-S2 described in FIG. 3A may include the display device DD-S2.

The display device DD-S2 may include the first non-folding portion NFS1, the first folding portion FS1, the second non-folding portion NFS2, the second folding portion FS2, and the third non-folding portion NFS3 that are sequentially arranged in the first direction DR1 in non-folding.

The first non-folding portion NFS1 may be arranged to overlap and correspond to the first non-folding area NFA1, the second non-folding portion NFS2 may be arranged to overlap and correspond to the second non-folding area NFA2, the third non-folding portion NFS3 may be arranged to overlap and correspond to the third non-folding area NFA3, the first folding portion FS1 may be arranged to overlap and correspond to the first folding area FA1, and the second folding portion FS2 may be arranged to overlap and correspond to the second folding area FA2.

In folding of the display device DD-S2, the first folding portion FS1 may have a first curvature and the second folding portion FS2 may have a second curvature. The first curvature and the second curvature may be different from each other. For example, the second curvature may be greater than the first curvature.

In the folded display device DD-S2, the second folding portion FS2 may be folded asymmetrically. That is, the center C2 of the second curvature of the second folding portion FS2 may be inclined closer to the first non-folding portion NFS1, and as a result, the thickness of the folded display device DD-S2 may be reduced with respect to the third direction DR3.

The center C2 of the second curvature may be located between a midplane MP between the second non-folding portion NFS2 and the third non-folding portion NFS3 and the first non-folding portion NFS1. The midplane MP may be defined as a plane between midpoints of a plane of the second non-folding portion NFS2 and a plane of the third non-folding portion NFS3, which are parallel to each other.

In folding of the display device DD-S2, the first volume V1 from the midplane MP to the second folding portion FS2 in the direction toward the first non-folding portion NFS1 may be greater than the second volume V2 from the midplane MP to the second folding portion FS2 in a direction opposite the direction toward the first non-folding portion NFS1. Specifically, when the folded display device DD-S2 is viewed from a plane defined by the first direction DR1 and the third direction DR3, an area from the midplane MP to the second folding portion FS2 above the midplane MP may be greater than an area from the midplane MP to the second folding portion FS2 under the midplane MP. The direction along the third direction DR3 will be referred to as an upper side, and the direction opposing the direction will be referred to as a lower side.

With respect to the non-folded display device DD-S2, the second folding portion FS2 may include a reverse curvature portion RFS that is folded according to a third curvature, a constant curvature portion FFS that is folded according to a second curvature, and a non-curvature portion AFS, which are sequentially arranged.

The reverse curvature portion RFS may be a region formed to have the third curvature in the second folding portion FS2 as the second folding portion FS2 is inclined toward the first non-folding portion NFS1. The third curvature of the reverse curvature portion RFS may be less than the second curvature of the constant curvature portion FFS.

In the folded display device DD-S2, the center C3 of the third curvature may be located on the top surface of the second non-folding portion NFS2 with respect to the third direction DR3. The line connecting the center C2 of the second curvature to the center C3 of the third curvature may pass through the display device DD-S1.

With the foregoing configuration, the display device DD-S2 may have a less thickness when folded, and thus the portability and compressibility of the display device DD-S2 and the electronic device ED-S2 including the display device DD-S2 may be improved.

Although a display device DD and the electronic device ED that are folded twice are illustrated and described in FIGS. 1 to 3B, the disclosure is not limited thereto and may be applied to the display device DD and the electronic device ED that are folded twice or more. The disclosure may be applied to a multi-fold display device.

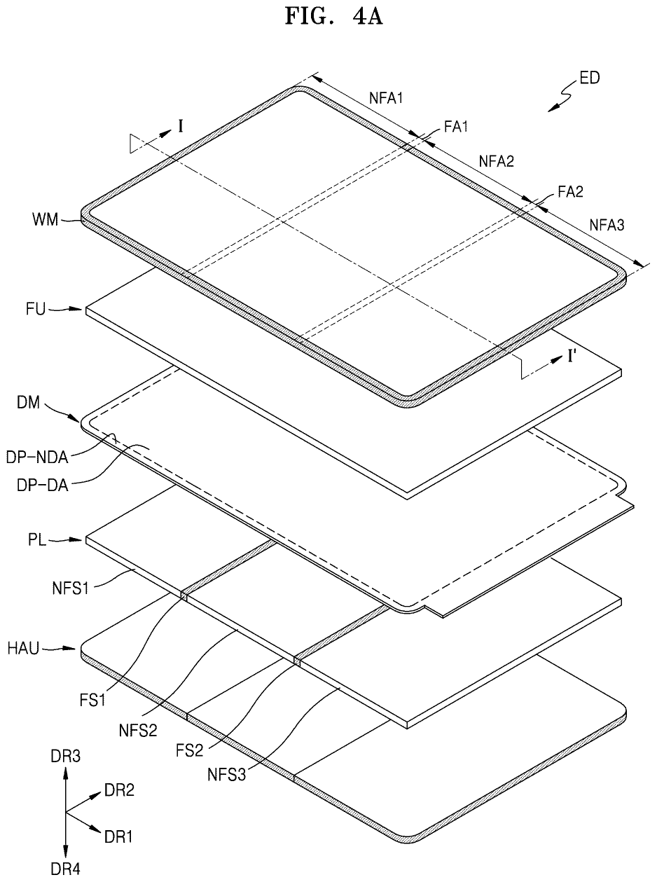

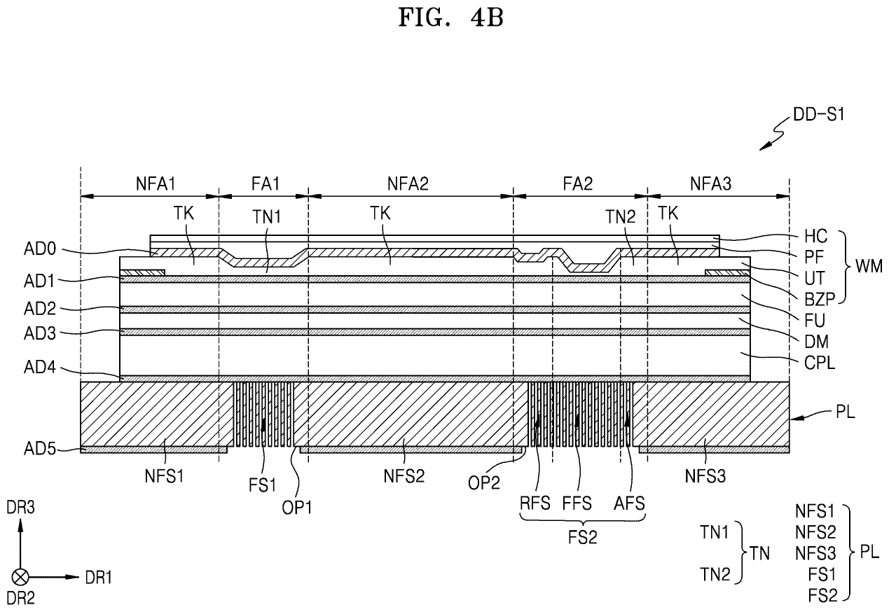

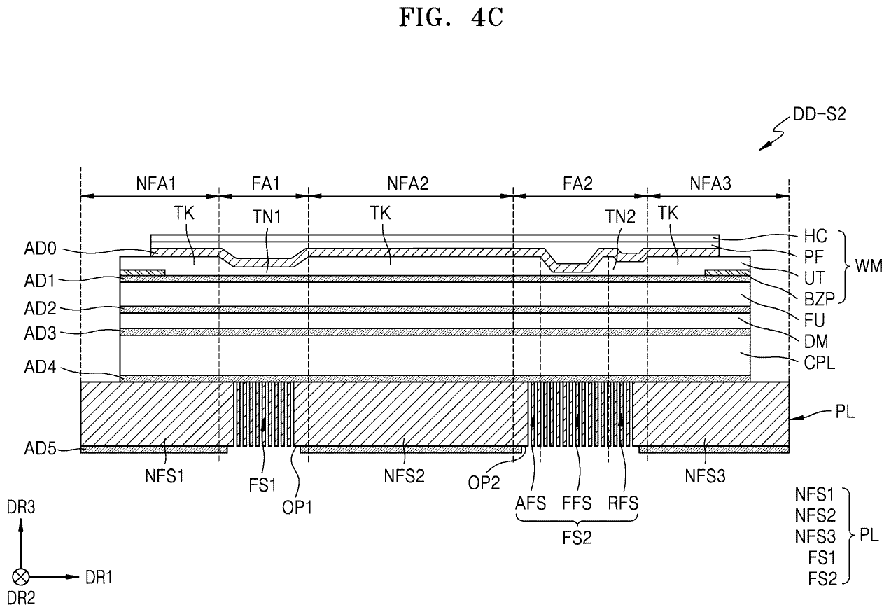

FIG. 4A is an exploded perspective view of an electronic device according to an embodiment of the disclosure, FIG. 4B is a cross-sectional view illustrating that the display device of FIG. 2B is unfolded, and FIG. 4C is a cross-sectional view illustrating that the display device of FIG. 3B is unfolded.

Referring to FIGS. 4A to 4C, the electronic device ED according to an embodiment may include a window WM, an upper film FU, a display module DM, a lower film CPL, a plate PL, and a housing HAU. The electronic device ED may include adhesive layers AD0, AD1, AD2, AD3, AD4, and AD5 arranged between the components to couple adjacent components to each other.

The electronic device ED according to an embodiment may further include a hinge member that guides the folding state. The hinge member may be arranged on the bottom of the plate PL. In FIG. 4A, the electronic module area EMA described with reference to FIG. 1 and electronic modules arranged under the electronic module area EMA are not illustrated.

The window WM may be arranged on the display module DM. The window WM may cover the entire top surface of the display module DM. The window WM may include an optically transparent insulating material.

The window WM may include a thin film glass substrate UT, a window protective layer PF on the thin film glass substrate UT, and a bezel pattern BZP. The window WM according to an embodiment may further include a functional layer HC on the window protective layer PF.

The window protective layer PF and the thin film glass substrate UT may be coupled by an adhesive layer AD0. The adhesive layer AD0 may include any one of a PSA film or an OCA layer. Hereinbelow, the adhesive layer described herein may include any one of a PSA film or an OCA layer, and a redundant description will be omitted.

The window protective layer PF may be arranged on the thin film glass substrate UT.

The window protective layer PF may include, for example, a synthetic resin film. The synthetic resin film of the window protective layer PF may include polyimide, polycarbonate, polyamide, triacetylcellulose, polymethylmethacrylate, or polyethylene terephthalate.

The functional layer HC may be arranged on the window protective layer PF. The functional layer HC may include at least one of a hard coating layer, an anti-fingerprint layer, and an anti-reflection layer. In an example case in which the functional layer HC includes a hard coating layer, a thickness of the functional layer HC may range from 3 μm to 10 μm.

The thin film glass substrate UT may be arranged under the window protective layer PF. The thickness of the thin film glass substrate UT may range from 25 μm to 100 μm. The thin film glass substrate UT may be chemically enhanced glass. The thin film glass substrate UT may minimize the occurrence of wrinkles in spite of repetition of folding and unfolding.

The bezel pattern BZP may overlap the peripheral area F-NAA illustrated in FIG. 1. The bezel pattern BZP may be arranged on the rear surface of the thin film glass substrate UT. FIGS. 4B and 4C show an example of the bezel pattern BZP arranged on the rear surface of the thin film glass substrate UT. Without being limited thereto, the bezel pattern BZP may also be arranged between the window protective layer PF and the thin film glass substrate UT. The bezel pattern BZP may be a colored light-shielding film that may be formed, for example, by a coating method. The bezel pattern BP may include a base material and a dye or pigment mixed into the base material.

The window WM and the upper film FU may be coupled through a first adhesive layer AD1.

The upper film FU may be arranged between the window WM and the display module DM. The upper film FU may absorb shock applied to the front surface of the electronic device ED. The upper film FU may include a synthetic resin film. The synthetic resin film may include polyimide, polycarbonate, polyamide, triacetylcellulose, polymethylmethacrylate, or polyethylene terephthalate. In an embodiment of the disclosure, the upper film FU may be omitted.

The upper film FU and the display module DM may be coupled through a second adhesive layer AD2.

The display module DM may be arranged under the window WM. The display module DM may be flexible. The display module DM may include a display area DP-DA and a non-display area DP-NDA corresponding to the active area F-AA and peripheral area F-NAA of the electronic device ED illustrated in FIG. 1.

The display module DM may include a display panel for displaying an image and an input sensor for detecting an external input. The display panel may be a light-emitting display panel and is not particularly limited. For example, the display panel may be an organic light-emitting display panel or an inorganic light-emitting display panel. The light-emitting layer of the organic light-emitting display panel may include an organic light-emitting material. The light-emitting layer of the inorganic light-emitting display panel may include quantum dots, quantum rods, or the like.

The display panel may include a plurality of light-emitting units. The light-emitting units may be arranged in the display area DP-DA and respectively emit light of specific colors. In an example case in which a plurality of light-emitting layers are provided, the light-emitting units may respectively correspond to the light-emitting layers. Alternatively, in an example case in which the light-emitting layer is provided as a single layer, the light-emitting units may respectively correspond to color filters or color conversion members.

The input sensor may be arranged on the display panel. The input sensor may be driven in a capacitive manner. The input sensor may detect a position and/or a strength of a user's hand across the entire display area DP-DA. The input sensor may be formed on the display panel through a continuous process. In this case, the input sensor may be expressed as being ‘arranged directly’ on the display panel. The term ‘arranged directly’ may mean that no third component is arranged between the input sensor and the display panel. A separate adhesive layer may not be arranged between the input sensor and the display panel.

The display module DM and the lower film CPL may be coupled through a third adhesive layer AD3.

The lower film CPL may be arranged under the display module DM. The lower film CPL may have a selected color. The lower film CPL may prevent the rear surface of the display module DM from illustrating through by light while protecting the rear surface of the display module DM. The lower film CPL may be formed of a material having a high light absorption rate. The lower film CPL may include a flexible synthetic resin film. For example, the lower film CPL may include polyethylene terephthalate.

The lower film CPL may be coupled to the plate PL through a fourth adhesive layer AD4.

The plate PL may be arranged under the display module DM to protect the display module DM from an external impact. In an embodiment, the plate PL may include a metallic material or a polymeric material. For example, the plate PL may be formed of stainless steel, aluminum, or alloys thereof. According to an embodiment, the plate PL may include a reinforced fiber composite. The plate PL may include reinforced fibers arranged inside a matrix portion. The reinforced fibers may be carbon fibers or glass fibers. The matrix portion may include a polymer resin. The matrix portion may include a thermoplastic resin. For example, the matrix portion may include a polyamide resin or a polypropylene resin. For example, the reinforced fiber composite may include carbon fiber reinforced plastic (CFRP) or glass fiber reinforced plastic (GFRP).

The plate PL may include folding portions FS1 and FS2 and non-folding portions NFS1, NFS2, and NFS3. The first folding portion FS1 may overlap the first folding area FA1, and the second folding portion FS2 may overlap the second folding area FA2. The width of the first folding portion FS1 in the first direction DR1 may be less than the width of the second folding portion FS2 in the first direction DR1.

The first folding portion FS1 may include a plurality of holes which may be formed by penetrating the first folding portion FS1 in the third direction DR3. The first folding portion FS1, excluding the holes, may have a slit shape on a plane.

The second folding portion FS2 may include a plurality of holes which may be formed by penetrating the second folding portion FS2 in the third direction DR3. The second folding portion FS2, excluding the holes, may have a slit shape on a plane.

The first non-folding portion NFS1 may overlap the first non-folding area NFA1, the second non-folding portion NFS2 may overlap the second non-folding area NFA2, and the third non-folding portion NFS3 may overlap the third non-folding area NFA3.

A fifth adhesive layer AD5 may be arranged on the bottom of the plate PL. The plate PL may be coupled to the hinge member that guides folding through the fifth adhesive layer AD5. The fifth adhesive layer AD5 according to an embodiment may include a first opening OP1 overlapping the first folding portion FS1 and a second opening OP2 overlapping the second folding portion FS2.

According to an embodiment, as the fifth adhesive layer AD5 includes the openings OP1 and OP2 overlapping corresponding folding portions among the folding portions FS1 and FS2, stress applied to the fifth adhesive layer AD5 overlapping the folding portions FS1 and FS2 may be reduced in spite of repetition of folding of the folding portions FS1 and FS2. Thus, the electronic device ED with improved folding characteristics may be provided.

The electronic device ED according to an embodiment may further include a lower support member arranged under the plate PL. The lower support member may include at least one of a support layer, a cushion layer, a shielding layer, and an interlayer bonding layer.

The housing HAU may be coupled to the window WM to define the appearance of the electronic device ED. The housing HAU may provide a space for housing the display module DM, the plate PL, the upper film FU, the lower film CPL, the hinge member, and the electronic module. Referring to FIG. 4B, specific configurations will be described to make the thickness of the display device DD-S1 and the electronic device ED-S1 including the same thinner when the electronic device ED-S1 is folded.

The display device DD-S1 may include the display module DM, the window WM arranged on the display module DM and including a bottom surface facing the display module DM and a top surface opposite the bottom surface and facing away from the display module DM, the lower film CPL arranged under the display module DM, and the plate PL arranged under the lower film CPL and including the first non-folding portion NFS1, the second non-folding portion NFS2, the third non-folding portion NFS3, the first folding portion FS1 between the first non-folding portion NFS1 and the second non-folding portion NFS2, and the second folding portion FS2 between the second non-folding portion NFS2 and the third non-folding portion NFS3.

Specifically, the second folding portion FS2 may include the reverse curvature portion RFS, the constant curvature portion FFS, and the non-curvature portion AFS, and the reverse curvature portion RFS, the constant curvature portion FFS, the non-curvature portion AFS, and then the third non-folding portion NFS3 may be sequentially arranged after the second non-folding portion NFS2 in the first direction DR1.

The window WM may include the thin film glass substrate UT and the window protective layer PF. The window protective layer PF may protect the thin film glass substrate UT and include an organic material, particularly a polymer resin. The thin film glass substrate UT may be glass that has been strength-reinforced by chemical or thermal methods.

That is, the thin film glass substrate UT may be stronger than the window protective layer PF. In an example case, the combined thickness of the thin film glass substrate UT and the window protective layer PF in the third direction DR3 is uniform, and a part where the thin film glass substrate UT is thin may be folded more easily than a part where the thin film glass substrate UT is thick.

The thin film glass substrate UT may include a thin film portion TN overlapping the first folding portion FS1 and the second folding portion FS2, and a thick film portion TK overlapping the first non-folding portion NFS1, the second non-folding portion NFS2, and the third non-folding portion NFS3. With respect to the third direction DR3, the thickness of the thin film portion TN may be less than the thickness of the thick film portion TK. That is, as the thickness of the thin film portion TN overlapping the folding portions FS1 and FS2 is thin, the folding portions FS1 and FS2 have less rigidity than the non-folding portions NFS1, NFS2, and NFS3 and thus may be bent in accordance with one or more embodiments of the present disclosure.

The thickness of the thin film glass substrate UT may continuously change between the thin film portion TN and the thick film portion TK. In other words, the thickness may continuously increase in the third direction DR3 from the thin film portion TN to the thick film portion TK, and the thickness may continuously decrease in the third direction DR3 from the thick film portion TK to the thin film portion TN.

As the thickness of the thin film glass substrate UT changes continuously, the thinnest portion of each thin film section TN may correspond to an area with the greatest curvature when the display device DD-S1 is folded in each folding portion FS1 or FS2.

The thin film portion TN may include a first thin film portion TN1 overlapping the first folding portion FS1 and a second thin film portion TN2 overlapping the second folding portion FS2. With reference to different areas of the second thin film portion TN2 of the unfolded display device DD-S1, the thickness of an area of the second thin film portion TN2 overlapping the reverse curvature portion RFS with respect to the third direction DR3 may be greater than the thickness of an area of the second thin film portion TN2 overlapping the constant curvature portion FFS. The thickness of the area of the second thin film portion TN2 overlapping the reverse curvature portion RFS may be less than the thickness of the area of the second thin film portion TN2 overlapping the non-curvature portion AFS.

In folding of the display device DD-S1, the thickness of the thin film glass substrate UT may be adjusted according to a desired curvature for each area. In an example of implementing an area of the thin film glass substrate UT to have a large curvature, the thin film glass substrate UT may have a low rigidity which facilitates folding. Embodiments of the present disclosure include adjusting the thickness of the thin film glass substrate UT to be less than or equal to a target thickness which supports such a low rigidity.

That is, as the third curvature of the reverse curvature portion RFS is less than the second curvature of the constant curvature portion FFS, the thickness of the second thin film portion TN2 overlapping the reverse curvature portion RFS may be set greater than the thickness of the second thin film portion TN2 overlapping the constant curvature portion FFS.

In an example case in which the first curvature of the first folding portion FS1 is less than the second curvature of the constant curvature portion FFS, the thickness of the first thin film portion TN1 may be greater than the thickness of the second thin film portion TN2 overlapping the constant curvature portion FFS. In an example case in which the first curvature of the first folding portion FS1 is greater than the third curvature of the reverse curvature portion RFS, the thickness of the first thin film portion TN1 may be less than the thickness of the second thin film portion TN2 overlapping the reverse curvature portion RFS.

In FIG. 4B, the thickness of the thin film glass substrate UT is illustrated as increasing again between where the second thin film portion TN2 overlaps the reverse curvature portion RFS and where the second thin film portion TN2 overlaps the constant curvature portion FFS, but the disclosure is not limited thereto, and the thin film glass substrate UT may be connected continuously (i.e., continuously formed) based on the degree of a curvature desired in the reverse curvature portion RFS and the constant curvature portion FFS. Referring to FIG. 4C, specific configurations will be described to make the thickness of the display device DD-S2 and the electronic device ED-S2 including the same thinner when the electronic device ED-S2 is folded.

The display device DD-S2 and the electronic device ED-S2 including the same may be applied in the same manner as described in FIG. 4B, except for the second thin film portion TN2 and the second folding portion FS2 that overlap the second folding portion FS2 in unfolding.

The second folding portion FS2 of the display device DD-S2 may include the reverse curvature portion RFS, the constant curvature portion FFS, and the non-curvature portion AFS, and the non-curvature portion AFS, the constant curvature portion FFS, the reverse curvature portion RFS, and then the third non-folding portion NFS3 may be sequentially arranged after the second non-folding portion NFS2 in the first direction DR1.

The thin film portion TN of the display device DD-S2 may include the first thin film portion TN1 overlapping the first folding portion FS1 and the second thin film portion TN2 overlapping the second folding portion FS2. With reference to the second thin film portion TN2 of the unfolded display device DD-S2, the thickness of an area of the second thin film portion TN2 overlapping the reverse curvature portion RFS with respect to the third direction DR3 may be greater than the thickness of an area of the second thin film portion TN2 overlapping the constant curvature portion FFS. The thickness of the area of the second thin film portion TN2 overlapping the reverse curvature portion RFS may be less than the thickness of the area of the second thin film portion TN2 overlapping the non-curvature portion AFS.

In folding of the display device DD-S2, the thickness of the thin film glass substrate UT may be adjusted according to a desired curvature for each area. In an example of implementing an area of the thin film glass substrate UT to have a large curvature, the thin film glass substrate UT may have a low rigidity which facilitates folding. Embodiments of the present disclosure include adjusting the thickness of the thin film glass substrate UT to be less than or equal to a target thickness which supports such a low rigidity.

That is, as the third curvature of the reverse curvature portion RFS is less than the second curvature of the constant curvature portion FFS, the thickness of the second thin film portion TN2 overlapping the reverse curvature portion RFS may be set greater than the thickness of the second thin film portion TN2 overlapping the constant curvature portion FFS.

For example, in an example case in which the first curvature of the first folding portion FS1 is less than the second curvature of the constant curvature portion FFS, the thickness of the first thin film portion TN1 may be greater than the thickness of the second thin film portion TN2 overlapping the constant curvature portion FFS. In an example case in which the first curvature of the first folding portion FS1 is greater than the third curvature of the reverse curvature portion RFS, the thickness of the first thin film portion TN1 may be less than the thickness of the second thin film portion TN2 overlapping the reverse curvature portion RFS.

In FIG. 4C, the thickness of the thin film glass substrate UT is illustrated as increasing again between where the second thin film portion TN2 overlaps the reverse curvature portion RFS and where the second thin film portion TN2 overlaps the constant curvature portion FFS, but the disclosure is not limited thereto, and the thin film glass substrate UT may be connected continuously based on the degree of a curvature desired in the reverse curvature portion RFS and the constant curvature portion FFS.

As described with reference to FIGS. 4B and 4C, the thickness of the thin film glass substrate UT may be set differently according to the desired curvature to induce asymmetry of the second folding portion FS2 and reduce the thickness of the display device DD.

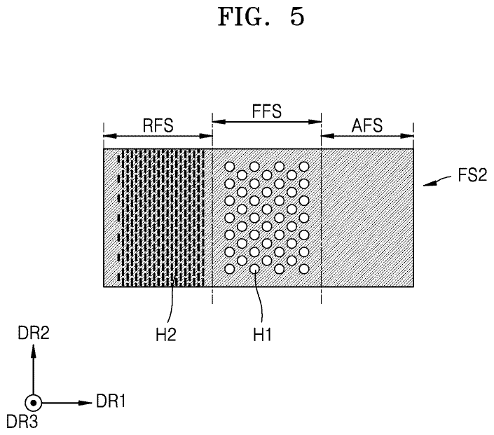

FIG. 5 is a plan view illustrating a part of a folding unit according to an embodiment of the disclosure. Specifically, FIG. 5 is a plan view specifically illustrating an example of a second folding portion. Referring to FIG. 5, the second folding portion FS2 may include the reverse curvature portion RFS, the non-curvature portion AFS, and the constant curvature portion FFS between the reverse curvature portion RFS and the non-curvature portion AFS.

In folding of the display device DD according to the disclosure, the constant curvature portion FFS of the second folding portion FS2 may be bent the most, that is, the second curvature of the constant curvature portion FFS may be greatest. In the second folding portion FS2, the reverse curvature portion RFS may be bent more than the non-curvature portion AFS, but the third curvature of the reverse curvature portion RFS may be less than the second curvature of the constant curvature portion FFS.

In order to implement this second folding portion FS2, holes can be formed in the constant curvature portion FFS and the reverse curvature portion RFS to make the rigidity of the constant curvature portion FFS, the reverse curvature portion RFS, and the non-curvature portion AFS different. In other words, even in an example case in which the entire second folding portion FS2 is formed of the same material, many and large holes may be formed in an area where the display device DD is foldable (or is to be folded) according to a large curvature, such that the second folding portion FS2 may be folded asymmetrically.

The constant curvature portion FFS may include a plurality of first holes H1, and the reverse curvature portion RFS may include a plurality of second holes H2. A ratio of an area of all the first holes H1 to an area of the constant curvature portion FFS may be greater than a ratio of an area of all the second holes H2 to an area of the reverse curvature portion RFS. For example, the size of the first hole H1 may be greater than the size of the second hole H2. For example, in an example case in which the size of the first hole H1 is the same as the size of the second hole H2, the first holes H1 may be formed more densely than the second holes H2. In other words, a distance between the first holes H1 may be less than a distance between the second holes H2.

Each edge of the constant curvature portion FFS and the reverse curvature portion RFS along the first direction DR1 may include areas that are flat and do not have a curvature even when the display device DD is folded. In this case, the second folding portion FS2 may be implemented such that no holes are formed in the first direction DR1 at an edge of the constant curvature portion FFS and an edge of the reverse curvature portion RFS.

The display device DD according to an embodiment may be applied to various electronic devices ED. The electronic device ED according to an embodiment may include the display device DD described herein, and may further include a module or device having additional functions in addition to the display device DD.

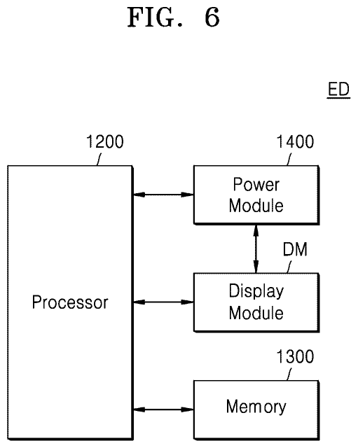

FIG. 6 is a block diagram of an electronic device according to an embodiment of the disclosure. Referring to FIG. 6, the electronic device ED according to an embodiment may include the display module DM, a processor 1200, a memory 1300, and a power module 1400.

The processor 1200 may include at least one of a central processing unit (CPU), an application processor (AP), a graphic processing unit (GPU), a communication processor (CP), an image signal processor (ISP), and a controller.

The memory 1300 may store data information supportive of the operation of the processor 1200 or the display module DM. In an example case in which the processor 1200 executes an application stored in the memory 1300, an image data signal and/or an input control signal may be transmitted to the display module DM, and the display module DM may process the received signal and output the image information through a display screen.

The power module 1400 may include a power supply module, such as a power adapter, a battery device, or the like, and a power conversion module that converts power supplied by the power supply module to generate power for the operation of the electronic device ED.

At least one of the components of the electronic device ED may be included in the display device DD according to the embodiments described herein. Some of the individual modules functionally included in a module may be included in the display device DD and others may be provided separately from the display device. For example, the display device may include the display module 1100, and the processor 1200, the memory 1300, and the power module 1400 may be provided in the form of other devices in the electronic device ED other than the display device DD.

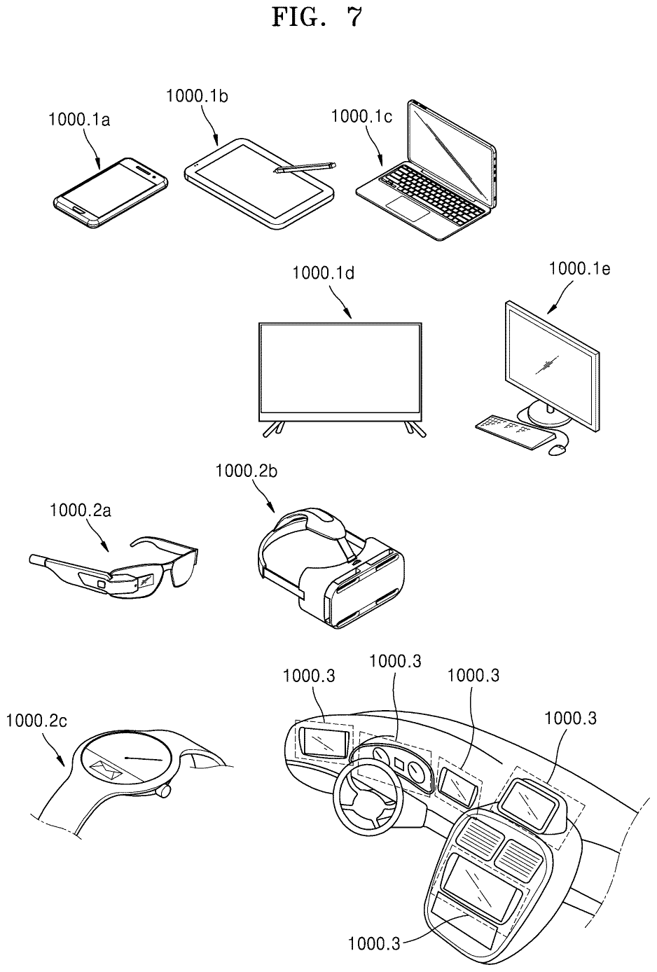

FIG. 7 illustrates schematic diagrams of an electronic device according to various embodiments. Referring to FIG. 7, various electronic devices to which the display device DD according to embodiments is applied may include not only image display electronic devices such as a smart phone 1000.1a, a tablet PC 1000.1b, a laptop computer 1000.1c, a TV 1000.1d, a desk monitor 1000.1e, or the like, but also wearable electronic devices including display modules such as smart glasses 1000.2a, a head mounted display 1000.2b, a smart watch 1000.2c, or the like, and vehicle electronic devices 1000.3 including display modules such as an instrument panel, a center fascia, a center information display (CID) arranged on a dashboard, a room mirror display, or the like of vehicles.

According to embodiments of the disclosure, a thinner display device may be provided by asymmetrically folding a foldable display device. However, effects that may be obtained through the disclosure are not limited to the effects described herein, and other technical effects not mentioned may be clearly understood by those of ordinary skill in the art from the description of the disclosure described herein.

Each of the embodiments described herein may be implemented independently, but it goes without saying that the structure of each embodiment may be applied in combination to other embodiments.

Although the disclosure has been described with reference to an example illustrated in the drawings, it will be understood by those of ordinary skill in the art that various modifications and equivalent other examples may be made from the illustrated example. Accordingly, the true technical scope of the disclosure should be defined by the technical spirit of the appended claims.

Specific implementations described in the embodiments are examples and do not limit the scope of the embodiments in any way. Unless there is specific mentioning of a component being, for example, “essential” or “important”, the component is not necessarily limited to being a required component in accordance with one or more embodiments of the present disclosure.

In the specification (especially, claims) of the disclosure, the use of the term “the” and similar indicators thereof may correspond to both the singular and the plural. For cases of a range described in the embodiments, the range includes the disclosure to which an individual value falling within the range is applied (unless stated otherwise), and is the same as the description of an individual value constituting the range in the description of the disclosure. Finally, unless there is an apparent description of the order of operations constituting the method according to embodiments or a contrary description thereof, the operations may be performed in an appropriate order. However, the embodiments are not necessarily limited according to the describing order of the operations. The use of all examples or example terms in the present disclosure are to simply describe the embodiments in detail, and unless the range of the embodiments is not limited by the examples or the example terms unless limited by the claims. In some aspects, it may be understood by those of ordinary skill in the art that various modifications, combinations, and changes may be made according to design conditions and factors within the scope of the appended claims or equivalents thereof.

What is claimed is:

1. A display device comprising:
a display module;
a window arranged on the display module and comprising:
a bottom surface facing the display module; and
a top surface opposite the bottom surface and facing away from the display module;
a lower film arranged under the display module; and
a plate arranged under the lower film and comprising:
a first non-folding portion,
a second non-folding portion,
a third non-folding portion,
a first folding portion between the first non-folding portion and the second non-folding portion, and
a second folding portion between the second non-folding portion and the third non-folding portion,
wherein:
a first curvature of the first folding portion and a second curvature of the second folding portion are different from each other in a folded state of the display device, and
a center of the second curvature is located between the first non-folding portion and a midplane between the second non-folding portion and the third non-folding portion.

2. The display device of claim 1, wherein the second curvature is greater than the first curvature.

3. The display device of claim 1, wherein in the folded state, a first volume from the midplane to the second folding portion in a direction toward the first non-folding portion is greater than a second volume from the midplane to the second folding portion in a direction opposite the direction toward the first non-folding portion.

4. The display device of claim 1, wherein the second folding portion comprises a reverse curvature portion folded according to a third curvature, a constant curvature portion folded according to the second curvature, and a non-curvature portion, which are sequentially arranged.

5. The display device of claim 4, wherein:
the constant curvature portion comprises a plurality of first holes, and
the reverse curvature portion comprises a plurality of second holes.

6. The display device of claim 5, wherein a size of each first hole of the plurality of first holes is greater than a size of each second hole of the plurality of second holes.

7. The display device of claim 4, wherein the third curvature is less than the second curvature.

8. The display device of claim 4, wherein:
the window comprises a thin film glass substrate,
the thin film glass substrate comprises:
a thin film portion overlapping the first folding portion and the second folding portion; and
a thick film portion overlapping the first non-folding portion, the second non-folding portion and the third non-folding portion, and
a thickness of the thick film portion is greater than a thickness of the thin film portion.

9. The display device of claim 8, wherein:
the thin film portion comprises a first thin film portion overlapping the first folding portion and a second thin film portion overlapping the second folding portion, and
a thickness of an area of the second thin film portion overlapping the reverse curvature portion is greater than a thickness of an area of the second thin film portion overlapping the constant curvature portion.

10. The display device of claim 9, wherein the thickness of the area of the second thin film portion overlapping the reverse curvature portion is less than a thickness of an area of the second thin film portion overlapping the non-curvature portion.

11. A display device comprising:
a display module;
a window arranged on the display module and comprising:
a bottom surface facing the display module; and
a top surface opposite the bottom surface and facing away from the display module;
a lower film arranged under the display module; and
a plate arranged under the lower film and comprising:
a first non-folding portion,
a second non-folding portion,
a third non-folding portion,
a first folding portion between the first non-folding portion and the second non-folding portion, and
a second folding portion between the second non-folding portion and the third non-folding portion,
wherein, in a folded state of the display device:
the first folding portion is folded according to a first curvature, and the second folding portion is folded according to a second curvature, and
with respect to a midplane between the second non-folding portion and the third non-folding portion, a first volume from the midplane to the second folding portion in a direction toward the first non-folding portion is greater than a second volume from the midplane to the second folding portion in a direction opposite the direction toward the first non-folding portion.

12. The display device of claim 11, wherein the second curvature is greater than the first curvature.

13. The display device of claim 11, wherein:
a first curvature of the first folding portion and a second curvature of the second folding portion are different from each other in folding, and
a center of the second curvature is located between the midplane and the first non-folding portion.

14. The display device of claim 11, wherein the second folding portion comprises a reverse curvature portion folded according to a third curvature, a constant curvature portion folded according to the second curvature, and a non-curvature portion, which are sequentially arranged.

15. The display device of claim 14, wherein:
the constant curvature portion comprises a plurality of first holes, and
the reverse curvature portion comprises a plurality of second holes.

16. The display device of claim 15, wherein a size of each first hole of the plurality of first holes is greater than a size of each second hole of the plurality of second holes.

17. The display device of claim 14, wherein the third curvature is less than the second curvature.

18. The display device of claim 14, wherein:
the window comprises a thin film glass substrate,
the thin film glass substrate comprises:
a thin film portion overlapping the first folding portion and the second folding portion; and
a thick film portion overlapping the first non-folding portion, the second non-folding portion and the third non-folding portion, and
a thickness of the thick film portion is greater than a thickness of the thin film portion.

19. The display device of claim 18, wherein:
the thin film portion comprises a first thin film portion overlapping the first folding portion and a second thin film portion overlapping the second folding portion, and
a thickness of an area of the second thin film portion overlapping the reverse curvature portion is greater than a thickness of an area of the second thin film portion overlapping the constant curvature portion.

20. An electronic device comprising a display device,
wherein the display device comprises:
a display module;
a window arranged on the display module and comprising:
a bottom surface facing the display module; and
a top surface opposite the bottom surface and facing away from the display module;
a lower film arranged under the display module; and
a plate arranged under the lower film and comprising:
a first non-folding portion,
a second non-folding portion,
a third non-folding portion,
a first folding portion between the first non-folding portion and the second non-folding portion, and
a second folding portion between the second non-folding portion and the third non-folding portion,
wherein:
a first curvature of the first folding portion and a second curvature of the second folding portion are different from each other in a folded state of the display device, and
a center of the second curvature is located between the first non-folding portion and a midplane between the second non-folding portion and the third non-folding portion.
